(19) United States
(12) Patent Application Publication
(10) Pub. No.: US 2008/0179404 A1
(43) Pub. Date: Jul. 31, 2008

(54) METHODS AND APPARATUSES TO PRODUCE INLAYS WITH TRANSPONDERS

(75) Inventor: David Finn, Tourmakeady (IE)

Correspondence Address: GERALD E. LINDEN, 12925 LAROCHELLE CR., PALM BEACH GARDENS, FL, 33410, US

(73) Assignee: Advanced Microelectronic and Automation Technology Ltd., Tourmakeady (IE)

(21) Appl. No.: 12/045,043

(22) Filed: Mar. 10, 2008

Related U.S. Application Data
(63) Continuation-in-part of application No. 11/831,987, filed on Aug. 1, 2007.
Application No. 11/831,987 is a continuation-in-part of application No. 11/760,793, filed on Jun. 11, 2007.
(60) Provisional application No. 60/883,064, filed on Jan. 1, 2007.
(60) Provisional application No. 60/884,158, filed on Jan. 9, 2007.
(60) Provisional application No. 60/887,294, filed on Jan. 30, 2007.
(60) Provisional application No. 60/894,469, filed on Mar. 13, 2007.
(60) Provisional application No. 60/826,923, filed on Sep. 26, 2006.
(60) Provisional application No. 60/883,064, filed on Jan. 1, 2007.
(60) Provisional application No. 60/884,158, filed on Jan. 9, 2007.
(60) Provisional application No. 60/887,294, filed on Jan. 30, 2007.
(60) Provisional application No. 60/894,469, filed on Mar. 13, 2007.
(60) Provisional application No. 60/911,077, filed on Apr. 10, 2007.
(60) Provisional application No. 60/971,581, filed on Sep. 12, 2007.
(60) Provisional application No. 61/020,141, filed on Jan. 9, 2008.
(60) Provisional application No. 60/894,469, filed on Mar. 13, 2007.
(60) Provisional application No. 60/938,454, filed on May 17, 2007.

(51) Int. Cl. G06K 19/077; H01L 21/58; H01L 21/44; H01L 21/263

(52) U.S. Cl. 235/492; 438/119; 438/106; 438/759; 438/676; 257/E21.505; 257/E21.476; 257/E21.332

(57) ABSTRACT

A transponder chip module is recessed into the surface of a substrate, end portions of an antenna wire are held in place on terminal areas of the chip module by a patch which may be transparent to allow laser bonding of the wire to the terminal areas. A cover may be disposed over everything. Conductive glue or a solderable material may be used to connect the wire to the terminal areas. A recess for the chip module, and a channel for the antenna wire may be formed by laser ablation. The substrate may be Teslin™, PET/PETE or Polycarbonate. The antenna wire may have a diameter of 60 μm. A synthetic cushion material may be provided beneath the transponder chip module.

### CROSS-REFERENCE TO RELATED APPLICATIONS

This application claims benefit of and (for non-provisionals), is a continuation-in-part of, the following provisional and patent applications:

U.S. Provisional Application 60/894,469 filed Mar. 13, 2007 by Finn (“S8”), incorporated by reference herein.

U.S. patent application Ser. No. 11/831,987 filed Aug. 1, 2007 by Finn (“S12”), incorporated by reference herein, which claims priority from the following provisional and patent applications, all of which are incorporated by reference herein:
60/826,923 filed 26 Sep. 2006 by Finn (“S4”),
60/883,064 filed 1 Jan. 2007 by Finn (“S5”),
60/884,158 filed 9 Jan. 2007 by Finn (“S6”),
60/887,294 filed 30 Jan. 2007 by Finn (“S7”),
60/894,469 filed 13 Mar. 2007 by Finn (“S8”),
Ser. No. 11/733,756 filed 10 Apr. 2007 by Finn (“S9”),
60/938,454 filed 17 May 2007 by Finn (“S11ppa”),
Ser. No. 11/760,793 filed 11 Jun. 2007 by Finn (“S10”), and
Ser. No. 11/773,434 filed 5 Jul. 2007 by Finn (“S11”).

U.S. patent application Ser. No. 11/760,793 filed Jun. 11, 2007 by Finn (“S10”), incorporated by reference herein, which claims priority from the following provisional patent applications, all of which are incorporated by reference herein:
60/883,064 filed 1 Jan. 2007 by Finn (“S5”),
60/884,158 filed 9 Jan. 2007 by Finn (“S6”),
60/887,294 filed 30 Jan. 2007 by Finn (“S7”),
60/894,469 filed 13 Mar. 2007 by Finn (“S8”), and
60/938,454 filed 17 May 2007 by Finn (“S11”).

U.S. Provisional Application 60/911,077 Apr. 10, 2007 by Finn (“S9ppa”), incorporated by reference herein.

U.S. Provisional Application 60/971,581 Sep. 12, 2007 by Finn (“S14”), incorporated by reference herein.

U.S. Provisional Application 61/020,141 filed Jan. 9, 2008 by Finn (“S15”), incorporated by reference herein.

### TECHNICAL FIELD

The invention relates to a method for producing a secure inlay comprising a transponder unit mounted to a substrate, and which may be laminated forming an inlay sheath used in the manufacture of electronic book type security documents such as a passport.

### BACKGROUND

The conventional method of manufacturing a high frequency transponder site is to embed a wire conductor into a synthetic film in forming an antenna and bonding the wire ends of the antenna to the terminal areas of a radio frequency identification (RFID) chip or chip module. The chip or chip module resides in a recess formed by applying an ultrasonic stamp to the synthetic film resulting in an indent, or the chip or chip module resides in a window supported by an underlying layer of synthetic film.

The conventional method to manufacture a high frequency transponder inlay for an electronic passport or identity document is to cold laminate the cover material of the passport using hot melt glue to a Teslin™ layer containing an embedded antenna connected to an RFID chip module. The cover material is coated heavyweight cotton with a thickness of approximately 400 microns, the hot melt glue is applied under light pressure, at an application temperature of 150, 170 or 200° C. (degrees Celsius) and having a thickness of approximately 30 microns, the Teslin layer containing the transponder unit is approximately 355 microns in thickness.

Teslin™ is a synthetic printing media, manufactured by PPG Industries. Teslin™ is a waterproof synthetic material that works well with an Inkjet printer, Laser printer, or Thermal printer. Teslin™ is also single-layer, uncoated film, and extremely strong. In fact, the strength of the lamination peel of a Teslin™ sheet is 2-4 times stronger than other coated synthetic and coated papers. Teslin™ comes in the sizes of 7 mil to 18 mil, though only sizes 10 mil and 14 mil are sized at 8.5″ by 11″, for printing with most consumer printers. Also available are perforated versions of Teslin, specifically, 2up, 6up, and 8up.

The module is typically a lead frame with the RFID chip protected by a mould mass. The thickness of the module is approximately 390 microns and the connection leads protruding from the module have a thickness of approximately 100 microns. The mould mass of the chip module resides in a cavity in the Teslin™ layer and the leads on each side of the module are positioned in a preformed trestle or indent in the Teslin™ layer. These indents in the Teslin™ layer for the leads are produced using an ultrasonic stamp. The embedded antenna with 4 or 5 turns of wire is connected to the chip module using thermal compression bonding. The antenna wire has a diameter of approximately 80 microns.

The inlay format can be a sheath with 3 transponder units having an overall dimension of 183 mm×405 mm, a sheath with 2 transponders can have the approximate dimensions of 108 mm×276 mm. In some cases the inlay sheath can have a binding strip 12 mm at its edge for the purpose of attaching the inlay to the passport booklet.

A number of security and reliability issues arise from the abovementioned method of producing an inlay for a security document. Firstly, the cold laminated inlay can be easily delaminated as it is only glued together allowing a potential fraud to take out the chip module without damaging it. Secondly, the indents in the Teslin layer may expand over time resulting in potential intermittent damage to the termination of the antenna wire to the lead frame. Thirdly, inlay manufacturing using the cold lamination technique results in fluctuating yields between 95% and 98%, which means that fallout in the field is inevitable.

The conventional method to interconnect the wire ends of an antenna to the terminal areas of a chip module is by means of thermal compression (TC) bonding. This method makes use of heat by passing pulses of electric current through a thermode and simultaneously applying pressure to cause a diffusion process between the wire and the lead frame of the chip module. The main disadvantages of thermal compression bonding are (i) the ageing of the thermode which requires regular replacement and (ii) residues of wire insulation remaining underneath the bonded wire which affects the long term reliability of the interconnection.

### An Inlay and Transponder of the Prior Art

FIGS. 1A and 1B illustrate an inlay substrate (or sheet) 100 having a plurality of transponder areas. A selected one of the transponder areas 102 constituting a single transponder is shown in detail. The vertical and horizontal dashed lines (in FIG. 1A) are intended to indicate that there may be additional transponder areas (and corresponding additional transponders) disposed to the left and right of, as well as above and below, the transponder area 102, on the inlay sheet 100. Such a plurality of transponders may be arranged in an array on the (larger) inlay sheet. As best viewed in FIG. 1B, the inlay sheet 100 may be a multi-layer substrate 104 comprising one or more upper (top) layers 104a and one or more lower (bottom) layers 104b.

A recess 106 may be formed in (through) the upper layer 104a, at a “transponder chip site”, so that a transponder chip 108 may be disposed in the recess, and supported by the lower layer 104b. The transponder chip 108 is shown having two terminals 108a and 108b on a top surface thereof. The transponder chip 108 may be a chip module, or an RFID chip.

Generally, the recess 106 is sized and shaped to accurately position the transponder chip 108, having side dimensions only slightly larger than the transponder chip 108 to allow the transponder chip 108 to be located within the recess. For example,
1. the transponder chip 108 may measure: 5.0×8.0 mm
2. the recess 106 may measure: 5.1×8.1 mm
3. the terminals 108a/b may measure: 5.0×1.45 mm
4. the wire (discussed below) may have a diameter between 60 and 112 μm

One millimeter (mm) equals one thousand (1000) micrometers (μm, “micron”).

In FIGS. 1A and 1B, the recess 106 may be illustrated with an exaggerated gap between its inside edges and the outside edges of the chip 108, for illustrative clarity. In reality, the gap may be only approximately 50 μm-100 μm (0.05 mm-0.1 mm).

In FIG. 1A the terminals 108a and 108b are shown reduced in size (narrower in width), for illustrative clarity. (From the dimensions given above, it is apparent that the terminals 108a and 108b can extend substantially the full width of the transponder chip 108.)

It should be understood that the transponder chip 108 is generally snugly received within the recess 106, with dimensions suitable that the chip 108 does not move around after being located within the recess 106, in anticipation of the wire ends 110a, 110b being bonded to the terminals 108a, 108b. As noted from the exemplary dimensions set forth above, only very minor movement of the chip 108, such as a small fraction of a millimeter (such as 50 μm-100 μm) can be tolerated.

As best viewed in FIG. 1A, an antenna wire 110 is disposed on a top surface (side) of the substrate, and may be formed into a flat (generally planar) coil, having two end portions 110a and 110b.

As best viewed in FIG. 1B, the antenna wire is “mounted” to the substrate, which includes “embedding” (countersinking) the antenna wire into the surface of the substrate, or “adhesively placing” (adhesively sticking) the antenna wire on the surface of the substrate. In either case (embedding or adhesively placing), the wire typically feeds out of a capillary 116 of an ultrasonic wire guide tool (not shown). The capillary 116 is typically disposed perpendicular to the surface of the substrate 100. The capillary 116 is omitted from the view in FIG. 1A, for illustrative clarity.

The antenna wire 110 may be considered “heavy” wire (such as 60 μm-112 μm), which requires higher bonding loads than those used for “fine” wire (such as 30 μm). Rectangular section copper ribbon (such as 60×30 μm) can be used in place of round wire.

The capillary 116 may be vibrated by an ultrasonic vibration mechanism (not shown), so that it vibrates in the vertical or longitudinal (z) direction, such as for embedding the wire in the surface of the substrate, or in a horizontal or transverse (y) direction, such as for adhesively placing the wire on the surface of the substrate. In FIG. 1B, the wire 110 is shown slightly spaced (in drawing terminology, “exploded” away) from the substrate, rather than having been embedded (countersunk) in or adhesively placed (stuck to) on the surface of the substrate.

The antenna wire 110 may be mounted in the form of a flat coil, having two ends portions 110a and 110b. The ends portions 110a and 110b of the antenna coil wire 110 are shown extending over (FIG. 1A) and may subsequently be connected, such as by thermal-compression bonding (not shown), to the terminals 108a and 108b of the transponder chip 108, respectively.

Examples of embedding a wire in a substrate, in the form of a flat coil, and a tool for performing the embedding (and a discussion of bonding), may be found in the aforementioned U.S. Pat. No. 6,698,089 (refer, for example, to FIGS. 1, 2, 4, 5, 12 and 13 of the patent). It is known that a coated, self-bonding wire will stick to a synthetic (e.g., plastic) substrate because when vibrated sufficiently to soften (make sticky) the coating and the substrate.

In FIG. 1B, the wire 110 is shown slightly spaced (in drawing terminology, “exploded” away) from the terminals 108a/b of the transponder chip 108, rather than having been bonded thereto, for illustrative clarity. In practice, this is generally the situation—namely, the end portions of the wires span (or bridge), the recess slightly above the terminals to which they will be bonded, in a subsequent step. Also illustrated in FIG. 1B is a “generic” bond head, poised to move down (see arrow) onto the wire 110b to bond it to the terminal 108b. The bond head 118 is omitted from the view in FIG. 1A, for illustrative clarity.

The interconnection process can be inner lead bonding (diamond tool), thermal compression bonding (thermode), ultrasonic bonding, laser bonding, soldering, ColdHeat soldering (Athalite) or conductive gluing.

As best viewed in FIG. 1A, in case the antenna wire 110 needs to cross over itself, such as is illustrated in the dashed-line circled area “c” of the antenna coil, it is evident that the wire should typically be an insulated wire, generally comprising a metallic core and an insulation (typically a polymer) coating. Generally, it is the polymer coating that facilitates the wire to be “adhesively placed” on (stuck to) a plastic substrate layer. (It is not always the case that the wire needs to cross over itself. See, for example, FIG. 4 of U.S. Pat. No. 6,698,089).

In order to feed the wire conductor back and forth through the ultrasonic wire guide tool, a wire tension/push mechanism (not shown) can be used or by application of compressed air it is possible to regulate the forward and backward movement of the wire conductor by switching the air flow on and off which produces a condition similar to the Venturi effect.

By way of example, the wire conductor can be self-bonding copper wire or partially coated self bonding copper wire, enamel copper wire or partially coated enamel wire, silver coated copper wire, un-insulated wire, aluminum wire, doped copper wire or litz wire.

### Laser Cutting and Laser Ablation

Laser cutting is a technology that uses a laser to cut materials, and is usually used in industrial manufacturing. Laser cutting works by directing the output of a high power laser, by computer, at the material to be cut. The material then either melts, burns, vaporizes away, or is blown away by a jet of gas, leaving an edge with a high quality surface finish. Industrial laser cutters are used to cut flat-sheet material as well as structural and piping materials. Some 6-axis lasers can perform cutting operations on parts that have been pre-formed by casting or machining.

Advantages of laser cutting over mechanical cutting vary according to the situation, but two important factors are the lack of physical contact (since there is no cutting edge which can become contaminated by the material or contaminate the material), and to some extent precision (since there is no wear on the laser). There is also a reduced chance of warping the material that is being cut as laser systems have a small heat affected zone.

Both gaseous CO₂ and solid-state Nd:YAG lasers are used for cutting, in addition to welding, drilling, surface treatment, and marking applications. Common variants of CO₂ lasers include fast axial flow, slow axial flow, transverse flow, and slab. CO₂ lasers are commonly “pumped” by passing a current through the gas mix (DC Excited) or using radio frequency energy (RF excited).

Laser ablation is the process of removing material from a solid surface by irradiating it with a laser beam. At low laser flux, the material is heated by the absorbed laser energy and evaporates or sublimates. At high laser flux, the material is typically converted to a plasma. Usually, laser ablation refers to removing material with a pulsed laser, but it is possible to ablate material with a continuous wave laser beam if the laser intensity is high enough. The depth over which the laser energy is absorbed, and thus the amount of material removed by a single laser pulse, depends on the material's optical properties and the laser wavelength. Laser pulses can vary over a very wide range of duration (milliseconds to femtoseconds) and fluxes, and can be precisely controlled.

The simplest application of laser ablation is to remove material from a solid surface in a controlled fashion. Laser machining and particularly laser drilling are examples; pulsed lasers can drill extremely small, deep holes through very hard materials. Very short laser pulses remove material so quickly that the surrounding material absorbs very little heat, so laser drilling can be done on delicate or heat-sensitive materials.

Also, laser energy can be selectively absorbed by coatings, particularly on metal, so CO₂ or Nd:YAG pulsed lasers can be used to clean surfaces, remove paint or coating, or prepare surfaces for painting without damaging the underlying surface. High power lasers clean a large spot with a single pulse. Lower power lasers use many small pulses which may be scanned across an area.

Laser engraving is the practice of using lasers to engrave or mark an object (it is also sometimes incorrectly described as etching, which involves the use of acid or a similar chemical). The technique does not involve tool bits which contact the engraving surface and wear out. This is considered an advantage over alternative engraving technologies where bit heads have to be replaced regularly.

The impact of laser engraving has been more pronounced for specially-designed “laserable” materials. These include polymer and some modern metal alloys.

### Related Patents and Publications

Reference is made to the following patents and published patent applications, all of which are incorporated by reference in their entirety herein.

U.S. Pat. No. 6,088,230 discloses a procedure for producing a chip mounting board and chip-mounting board thus produced. Procedure for producing a transponder unit (55) provided with at least one chip (16) and one coil (18), and in particular a chip card/chip-mounting board (17) wherein the chip and the coil are mounted on one common substrate (15) and the coil is formed by installing a coil wire (21) and connecting the coil-wire ends (19, 23) to the contact surfaces (20, 24) of the chip on the substrate. The chip and the coil are mounted on one common substrate and the coil is formed by installing a coil wire and connecting the coil-wire ends to the contact surfaces of the chip on the substrate. As a first step prior to the installation of the coil wire, one coil-wire end is connected to a first contact surface of the chip, the coil wire is then installed to form the coil, whereupon the leading end of the coil wire is connected to a second contact surface of the chip, while in the process of the coil-wire installation the coil wire (21) is bonded to the substrate at least in some locations.

U.S. Pat. No. 5,281,855 discloses a method and apparatus for facilitating interconnection of lead wires to an integrated circuit including the provision of an additional protective layer of insulation to the top of an integrated circuit chip or die and the provision of enlarged plated electrodes to the surface of the additional insulation to form enhanced bonding pads, such pads being electrically connected through the protective layers to the normal bonding pads of the integrated circuit device. The enhanced bonding pads are made of a soft conductive metal such that external wires to be attached thereto can be bonded to the pads using a thermal compression bonding technique.

U.S. Pat. No. 6,698,089 discloses a device for bonding a wire conductor. Device for the contacting of a wire conductor (113) in the course of the manufacture of a transponder unit arranged on a substrate (111) and comprising a wire coil (112) and a chip unit (115), wherein in a first phase the wire conductor (113) is guided away via the terminal area (118, 119) or a region accepting the terminal area and is fixed on the substrate (111) relative to the terminal area (118, 119) or the region assigned to the terminal area by a wire guide and a portal, and in a second phase the connection of the wire conductor (113) to the terminal area (118, 119) is effected by means of a connecting instrument (125). See also U.S. Pat. No. 6,233,818.

U.S. Pat. No. 6,233,818 discloses a method and device for bonding a wire conductor. Process and device for the contacting of a wire conductor (113) in the course of the manufacture of a transponder unit arranged on a substrate (111) and comprising a wire coil (112) and a chip unit (115), wherein in a first phase the wire conductor (113) is guided away via the terminal area (118, 119) or a region accepting the terminal area and is fixed on the substrate (111) relative to the terminal area (118, 119) or the region assigned to the terminal area, and in a second phase the connection of the wire conductor (113) to the terminal area (118, 119) is effected by means of a connecting instrument (125).

U.S. Pat. No. 6,088,230 discloses a procedure for producing a chip mounting board and chip-mounting board thus produced. Procedure for producing a transponder unit (55) provided with at least one chip (16) and one coil (18), and in particular a chip card/chip-mounting board (17) wherein the chip and the coil are mounted on one common substrate (15) and the coil is formed by installing a coil wire (21) and connecting the coil-wire ends (19, 23) to the contact surfaces (20, 24) of the chip on the substrate.

Canada Patent Application CA 2555034 discloses a method for the production of a book-type security document with at least one security cambric (15) and at least one transponder unit (21), characterized in that: at least one laminated layer (22, 23) is applied at least on one side of the at least one security cambric (15) and on at least one side of the at least one transponder unit (21); the at least one security cambric (15) and the at least one transponder unit (21) are fully encompassed by the laminated layers (22, 23) and that a circumferential, closed edge (24) is provided by the laminated layers (22, 231, and that a laminated layer sheath (25) is formed.

U.S. Pat. No. 7,176,053, incorporated by reference herein, discloses a laser ablation method for fabricating high performance organic devices. A laser ablation method is utilized to define the channel length of an organic transistor. A substrate is coated with a deposition of a metal or conductive polymer deposition, applied in a thin layer in order to enhance the resolution that can be attained by laser ablation. The laser ablation method can be used in a roll-to-roll process, and achieves speeds, volumes, prices and resolutions that are adequate to produce printed electronic technologies.

U.S. Pat. No. 6,956,182, incorporated by reference herein, discloses a method of forming an opening or cavity in a substrate for receiving an electronic component. A method of forming an opening or cavity in a substrate, for receiving an electronic component, consists of or includes providing a patterned opaque masking layer on or adjacent a first major surface of the substrate, the masking layer having an opening overlying the position where the cavity is to be made, removing material from the substrate by laser ablation through the opening thereby forming an opening or cavity of a suitable size for receiving said electronic component.

U.S. Pat. No. 6,140,707, incorporated by reference herein, discloses a laminated integrated circuit package. low-cost integrated circuit package is provided for packaging integrated circuits. In preferred embodiments, the package comprises a flexible circuit that is laminated to a stiffener using a dielectric adhesive, with the conductive traces on the flexible circuit facing toward the stiffener but separated therefrom by the adhesive. The conductive traces include an array of flip-chip attachment pads. A window is formed in the stiffener over the attachment pad array, such as by etching. The adhesive is then removed over the attachment pads by laser ablation, but left in place between the pads, thus forming a flip-chip attachment site. In preferred embodiments, this invention eliminates the need for high-resolution patterned adhesive, and it also eliminates the need for application of a solder mask at the flip-chip attachment site, because the remaining adhesive performs the solder mask function of preventing bridging between attachment pads. This package provides a die attachment site having a high degree of planarity due to tensile stresses formed in the flexible circuit and adhesive layers during lamination of those layers to the stiffener. Embodiments of this invention may be used with TBGA, frangible lead, and other packaging technologies.

US Publication 2007/0130754, incorporated by reference herein, discloses laser ablation prototyping of RFID antennas. A laser ablation radio frequency identification (RFID) antenna prototyping system includes an antenna design module, an ablation laser, and a laser driver. The antenna design module includes design parameters for an RFID antenna prototype. The laser driver communicates with the antenna design module and the ablation laser. The laser driver uses the design parameters to direct the ablation laser to heat a portion of a conductive ink layer that is formed on a substrate.

### GLOSSARY & DEFINITIONS

Unless otherwise noted, or as may be evident from the context of their usage, any terms, abbreviations, acronyms or scientific symbols and notations used herein are to be given their ordinary meaning in the technical discipline to which the disclosure most nearly pertains. The following terms, abbreviations and acronyms may be used throughout the descriptions presented herein and should generally be given the following meaning unless contradicted or elaborated upon by other descriptions set forth herein. Some of the terms set forth below may be registered trademarks (®).
chip As used herein, the word “chip” can encompass many configurations of a silicon die or a packaged chip. The silicon die for example can have metalized bumps to facilitate the direct connection of the wire ends of an antenna to form a transponder or tag device. A package chip can include various structures such as a tape automated bonding module, a chip module, a flip chip module, a lead frame, a chip carrier, a strap, an interposer or any form of packaging to facilitate transponder manufacturing.
inlay An inlay substrate typically has a plurality, such as array of transponder sites on a substrate which matches the position of the data or graphics on a printed sheet or holder/cover page of a smart card or electronic passport respectively.
   A secure inlay is similar to a conventional inlay but with additional features such as an additional RFID chip on the transponder site storing information about the production processes in the value chain as well as having personalization features integrated into the inlay such as a hologram, an anti-skimming material or security codes embedded into the inlay.
laser ablation Laser ablation is the process of removing material from a solid (or occasionally liquid) surface by irradiating it with a laser beam. At low laser flux, the material is heated by the absorbed laser energy and evaporates or sublimates. At high laser flux, the material is typically converted to a plasma. Usually, laser ablation refers to removing material with a pulsed laser, but it is possible to ablate material with a continuous wave laser beam if the laser intensity is high enough.
   The depth over which the laser energy is absorbed, and thus the amount of material removed by a single laser pulse, depends on the material's optical properties and the laser wavelength. Laser pulses can vary over a very wide range of duration (milliseconds to femtoseconds) and fluxes, and can be precisely controlled. This makes laser ablation very valuable for both research and industrial applications.
   The simplest application of laser ablation is to remove material from a solid surface in a controlled fashion. Laser machining and particularly laser drilling are examples; pulsed lasers can drill extremely small, deep holes through very hard materials. Very short laser pulses remove material so quickly that the surrounding material absorbs very little heat, so laser drilling can be done on delicate or heat-sensitive materials, including tooth enamel (laser dentistry).
RFID Short for “Radio Frequency Identification”. An RFID device interacts, typically at a limited distance, with a “reader”, and may be either “passive” (powered by the reader) or “active” (having its own power source, such as a battery).

### SUMMARY OF THE INVENTION

According to an embodiment of the invention, a transponder inlay may comprise: a substrate having a surface; a transponder chip module recessed into the surface of the substrate and having terminal areas; an antenna wire disposed on the surface of the substrate and having two end portions; the end portions of the antenna wire are disposed on the terminal areas of the chip module; and a patch holding in place the end portions of the antenna wire to the terminal areas of the chip module. The patch may be transparent, and may be adhesively attached to the substrate. A generally planar cover may be disposed over the substrate, chip module and patch, and may comprise a coated, heavy-weight cotton material. The chip module may comprise a mold mass and a lead frame, or it may comprise a bumped die. The substrate may comprise a material selected from the group consisting of Teslin, PET/PETE, and Polycarbonate. The antenna wire may have a diameter of 60 μm.

According to an embodiment of the invention, a method of forming a transponder inlay may comprise: recessing a transponder chip module in a surface of a substrate, wherein the chip module has terminal areas; mounting a wire to the surface of the substrate and forming an antenna; passing end portions of the antenna wire over the terminal areas; and placing a patch over the chip module with the wire ends of the antenna positioned over the terminals areas of the chip module. A laser may be used to bond the end portions of the antenna wire to the terminal areas by passing the beam through the transparent patch. A dollop of conductive glue or solderable material may be applied to an interface between the end portions of the wire and the terminal areas, and a laser may be used to heat the conductive glue or solderable material. The patch may be adhesively secured to the substrate. The patch may be hot laminated to the substrate. The chip module may be recessed into the substrate by pressing the chip module against the substrate using thermal energy. The chip module may be recessed into the substrate by milling a recess for receiving the transponder chip into the surface of the substrate. The milling may be performed with a laser. A cover may be mounted over the substrate, including the transponder chip module, wire and patch.

According to an embodiment of the invention, a method of forming a transponder inlay may comprise: mounting a chip module to a substrate; mounting an antenna wire to the substrate; connecting end portions of the antenna wire to terminal areas of the chip module using a laser; and performing at least one of: removing insulation from end portions of the wire; forming a recess in the substrate using laser ablation; and forming a channel for the antenna wire in the substrate. A cover may be mounted over the substrate, including the chip module and antenna wire.

According to an embodiment of the invention, a method of forming a recess in a substrate for a transponder chip module may comprise: forming a recess for the transponder chip module in a surface of the substrate, wherein the recess extends only partially through the substrate. A laser may be used to form the recess by ablating material from the substrate. The laser may be is scanned across the surface of the substrate to form the recess. The substrate may comprise Teslin. A synthetic cushion material may be provided, in the recess, between the transponder chip module and the substrate (beneath the chip module).

According to an embodiment of the invention, a method of mounting an antenna wire to a surface of a substrate for a transponder chip may comprise: forming a channel for the antenna wire in the surface of the substrate; and laying down the wire into the channel. The channel may be U-shaped, and may be formed by a mechanical tool, or by a hot mold process, or by a laser. The channel may have a depth which is less than a diameter of the wire, and as the wire is laid down into the channel, it is pressed further into the substrate. The substrate may comprise Teslin.

### BRIEF DESCRIPTION OF THE DRAWINGS

Reference will be made in detail to embodiments of the disclosure, examples of which may be illustrated in the accompanying drawing figures (FIGs). The figures are intended to be illustrative, not limiting. Although the invention is generally described in the context of these embodiments, it should be understood that it is not intended to limit the invention to these particular embodiments.

Certain elements in selected ones of the figures may be illustrated not-to-scale, for illustrative clarity. The cross-sectional views, if any, presented herein may be in the form of “slices”, or “near-sighted” cross-sectional views, omitting certain background lines which would otherwise be visible in a true cross-sectional view, for illustrative clarity. In some cases, hidden lines may be drawn as dashed lines (this is conventional), but in other cases they may be drawn as solid lines.

If shading or cross-hatching is used, it is intended to be of use in distinguishing one element from another (such as a cross-hatched element from a neighboring un-shaded element). It should be understood that it is not intended to limit the disclosure due to shading or cross-hatching in the drawing figures.

Elements of the figures may (or may not) be numbered as follows. The most significant digits (hundreds) of the reference number correspond to the figure number. For example, elements of FIG. 1 are typically numbered in the range of 100-199, and elements of FIG. 2 are typically numbered in the range of 200-299. Similar elements throughout the figures may be referred to by similar reference numerals. For example, the element 199 in FIG. 1 may be similar (and possibly identical) to the element 299 in FIG. 2. Throughout the figures, each of a plurality of elements 199 may be referred to individually as 199a, 199b, 199c, etc. Such relationships, if any, between similar elements in the same or different figures will become apparent throughout the specification, including, if applicable, in the claims and abstract.

FIG. 1A is a top view of a transponder site, according to the prior art.

FIG. 1B is a side, cross-sectional view, partially exploded, of a wire being mounted to the substrate of FIG. 1A (and bonded to the terminals of the chip), according to the prior art.

FIG. 2 is a cross-sectional view, partially exploded, illustrating a conventional method of forming a cold laminated inlay, according to the prior art.

FIG. 3 is a plan view illustrating a conventional method of making a transparent hot laminated inlay, according to the prior art.

FIG. 4 is a cross-sectional view, partially exploded, illustrating an embodiment of a hot laminated inlay, according to an embodiment of the invention.

FIG. 4A is a cross-section of a portion of the inlay of FIG. 4, illustrating to an embodiment of the invention.

FIG. 5 is a cross-sectional view, partially exploded, illustrating an embodiment of a hot laminated inlay using laser technology for direct connection and patching to protect the positioning of the antenna wires relative to the bumps (terminal areas) of the die (chip), according to an embodiment of the invention.

FIG. 5A is a top view of a portion of FIG. 5.

FIG. 6A is a cross-sectional view illustrating a design for a passport-type inlay, according to the prior art.

FIG. 6B is a cross-sectional view illustrating a design for a passport-type inlay, according to an embodiment of the invention.

FIG. 7 is a cross-sectional view illustrating a technique for removing insulation from wire, according to an embodiment of the invention.

FIG. 8 is a cross-sectional view illustrating a technique for forming a recess in a substrate, according to an embodiment of the invention.

FIG. 9 is a cross-sectional view illustrating a technique for mounting a wire in a substrate, according to an embodiment of the invention.

FIG. 10 is a cross-sectional view illustrating a technique for bonding a wire to a chip (or chip module), according to an embodiment of the invention.

FIG. 11 is a perspective view of an inlay having an antenna and a chip (or chip module), according to the invention.

### DETAILED DESCRIPTION OF THE INVENTION

Various “embodiments” of the invention will be discussed. An embodiment is an example or implementation of one or more aspects of the invention(s). Although various features of the invention may be described in the context of a single embodiment, the features may also be provided separately or in any suitable combination. Conversely, although the invention may be described herein in the context of separate embodiments for clarity, the invention may also be implemented in a single embodiment.

It should be understood that the phraseology and terminology employed herein is not to be construed as limiting, and is for descriptive purposes only.

The invention relates generally to secure inlays which may be single or multi-layer substrates containing HF (high frequency) and/or UHF (ultra-high frequency) radio frequency identification (RFID, transponder) chips and, more particularly, to techniques for mounting (including embedding in or positioning on) an antenna wire to the inlay substrate, and preparing end portions of the antenna wire for connecting to the terminals areas of a chip (such as an RFID transponder chip) or a chip module.

### DEFINITIONS

As used herein, an “inlay” is a generally planar substrate (or sheet), which may include several (a plurality of) distinct “transponder areas” (or “transponder sites”), arranged for example in a 3×6 array on the planar substrate. The inlay sheet may have one or more (multiple) layers, including one or more “top layers” and one or more “bottom layers”. A “transponder” may be fabricated in each “transponder area”. Each “transponder” may include an antenna, which is mounted to a surface (such as a top layer) of the substrate, and a “transponder chip” which is installed at a “transponder chip site” (or “site for the transponder chip”) on the substrate. The antenna is typically in the form of a flat coil having two ends, which are connected to bond pads (terminals) on the “transponder chip”. The “transponder chip” may be an individual integrated circuit (IC) chip, or a chip module (such as a chip mounted to a small substrate or a carrier). The “transponder chip site” of the “transponder” (“transponder area” of the “inlay sheet”) may comprise a recess (or window, or opening) extending through the top and one or more underlying layers of the substrate, such that the “transponder chip” can be installed in the recess, submerged below (or even with) the top surface of the planar substrate and supported by an underlying layer of the planar substrate. A window may extend completely through the planar substrate so that a transponder chip or chip module may be installed from an opposite (from the antenna) side of the planar substrate.

As used herein, the word “chip” can encompass many configurations of a silicon die or a packaged chip. The silicon die for example can have metalized bumps to facilitate the direct connection of the wire ends of an antenna to form a transponder or tag device. A packaged chip can include various structures such as a tape automated bonding module, a chip module, a flip chip module, a lead frame, a chip carrier, a strap, an interposer or any form of packaging to facilitate transponder manufacturing. Regarding metalized bumps on chips, normally chips (also referred to as “dice”, plural of “die”) have aluminum pads 100×100 microns in dimension. Gold bumps may be sputtered or plated onto the aluminum pads and rise 25 microns above the pads. Enhanced pads or so-called “mega bumps” can be large and can be mounted over the active structure of a die.

An inlay substrate typically has a plurality, such as an array of transponder sites on a substrate, which matches the position of the data or graphics on a printed sheet or holder/cover page of a smart card or electronic passport respectively. An “inlay” is generally a semi-finished product that requires additional layers of material (e.g., printed sheet) to complete a “final product” (e.g., electronic passport or smart card).

An inlay with an array of transponder sites may be produced by placing sheets of synthetic material or coated paper on top of each other with an antenna or antennae and electronic components at each site sandwiched between layers of sheet material. To integrate the electronic components such as an RFID chip module, a cavity at each site is punched into one or more of the top layers, in order to protect the chip modules during hot lamination.

When the term “transponder” is used herein, it may be taken to include any chip suitable for use in an inlay, such as an RFID chip. RFID is short for “Radio Frequency Identification”. An RFID device interacts, typically at a limited distance, with a “reader”, and may be either “passive” (powered by the reader) or “active” (having its own power source, such as a battery). As used herein, a transponder may comprise an RFID chip (either passive or active) connected to an antenna. (A “transponder chip” may be an “RFID chip”.)

When the term “chip” is used herein, it may be taken to include a chip module, or a chip unit. Generally, as used herein, “chip” is intended to mean RFID or transponder chip. Also, where applicable, a “chip” may refer to a die, chip module or carrier or “strap”.

Regarding metalized bumps on chips, normally chips (also referred to as “dice”, plural of “die”) have aluminum pads 100×100 microns in dimension. Gold bumps may be sputtered or plated onto the aluminum pads and rise 25 microns above the pads. Enhanced pads or so-called “mega bumps” can be large and can be mounted over the active structure of a die.

When the term “wire” is used herein, it may be taken to include any elongate means for conveying or radiating signals, such as metallic wire (such as gold, aluminium, copper, silver), of any profile (such as round or rectangular), either bare, coated or colour coated, as well as optical fibers.

When the term “antenna” is used herein, it may be taken to include a simple coil antenna comprising wire having a number of turns, and two ends, a dipole antenna having two wire segments with two inner ends, or any other antenna configuration suitable for connection to a chip or chip module in an inlay.

When the term “mounting” is used herein (in conjunction with wire) it may be taken to include embedding or countersinking the wire into a surface of the inlay substrate and/or adhesively placing (bonding or sticking) the wire to the surface of the substrate. In some contexts, the term “embedding” may be be taken to include adhesively placing, if appropriate in the context (such as when describing mounting a self-bonding wire)—in other words, “embedding” may sometimes be used to mean “mounting” (which includes both “embedding” and “adhesively placing”).

When the term “bonding” is used herein, it may be taken to include any means of interconnecting (or simply “connecting”), both physically and electrically, a wire, or an end of the wire, or an end portion of the wire, to a terminal or connection pad on a chip or chip module. (Bonding typically comprises a kind of welding, but can include adhesively bonding and soldering.) The interconnection process can for example be inner lead bonding (heated diamond tool), thermal compression bonding (thermode), ultrasonic bonding or laser welding.

Generally, as used herein describing embodiments of the invention, the “transponder chip” is an electronic component comprising (having at least) two terminals, which may be a single chip, or a module comprising (having at least) a chip. Generally, the two terminals of the chip or module are interconnected with corresponding two end portions of the antenna wire which is mounted to a top surface of a substrate, which may be a multilayer substrate.

Generally, as used herein describing embodiments of the invention, the transponder chip is disposed in a “recess” or “cavity” which is an opening extending at least partially through the substrate. A “window” is generally an opening that may extend fully through the substrate.

A “slot” is another opening (or hole) extending through the substrate next to a recess, cavity or window. In some embodiments, any of recess, cavity, window, or slot (and combinations thereof) may be used, and when the term “recess” is used, it should be understood to include all the variations and combinations, as may be appropriate from the context.

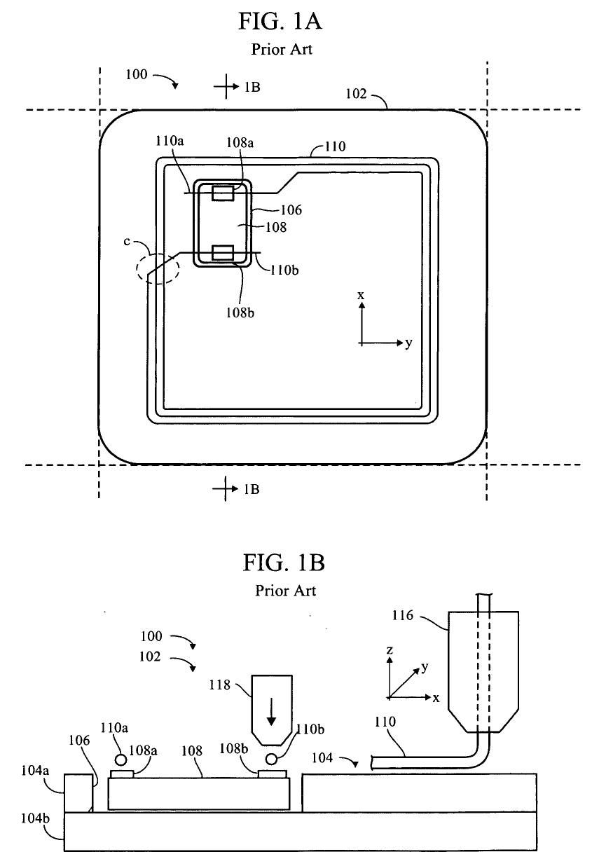

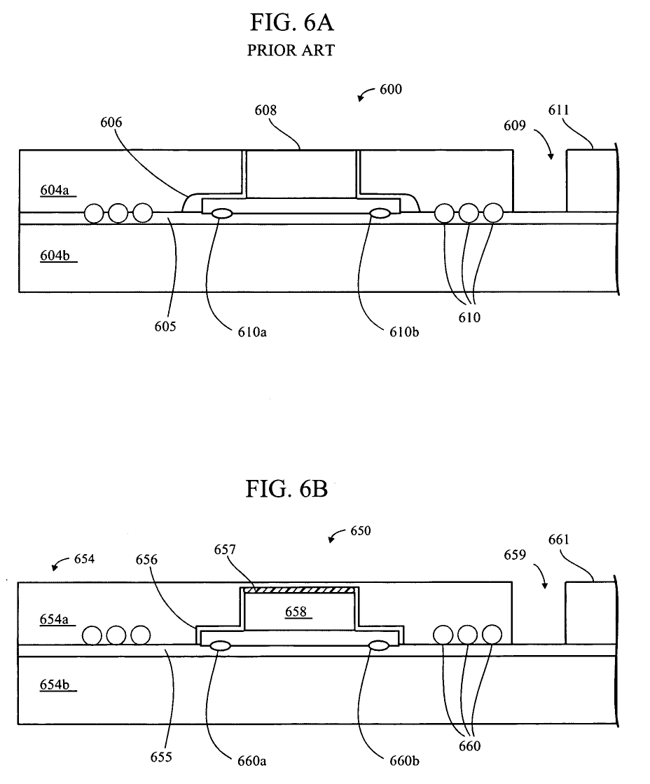

As used herein, a “recess” is generally (and usually) an opening extending only partially through a (typically) multilayer substrate (the recess may extend completely through top layers only), as may be exemplified by the recess 106 (FIG. 1B). The term “cavity” may be used interchangeably with “recess”. A “window” is generally (and usually) an opening extending completely through a substrate (whether or not multilayer), as may be exemplified by the opening 56 in FIG. 6 of U.S. Pat. No. 6,698,089.

### SOME EMBODIMENTS OF THE INVENTION

In some embodiments, the present invention may make use of, and incorporate, various techniques that may have been disclosed in previously-filed, provisional patent applications, as follows:

The present invention may make use of techniques such as may have been disclosed in U.S. Provisional Application 60/826,923 filed Sep. 26, 2006 by Finn (“S4”), incorporated by reference herein. The S4 provisional application describes, for example, a method of how the wire ends of an antenna may be formed as a free standing loop in preparation for interconnection with a terminal area of an RFID chip. The antenna wire is embedded into a non conducting substrate and the wire is looped around the first bond position so as to return the wire to the substrate, where the wire is then embedded into the non-conducting substrate to form an antenna, meaning that the wire is left to dangle near the terminal area.

The present invention may make use of techniques such as may have been disclosed in U.S. Provisional Application 60/883,064 filed 1 Jan. 2007 by Finn (“S5”), incorporated by reference herein. The S5 provisional application describes, for example, a method of removing the insulation coat of the wire conductor before interconnection, by passing the wire conductor through a laser tunnel, driven by a glass fiber connected to a multiplexing diode laser, before the wire conductor is directed to the ultrasonic wire guide tool.

The present invention may make use of techniques such as may have been disclosed in U.S. Provisional Application 60/884,158 filed 9 Jan. 2007 by Finn (“S6”) incorporated by reference herein. The S6 provisional patent application describes, for example, a practical example of the insulation removal unit using a 70 watt diode laser (808 nm) connected to a glass fiber (400 microns), to remove a section of insulation layer (polyurethane) with a thickness of 2 to 4 microns from a moving wire conductor having a diameter of approximately 112 microns, by directing the laser beam to the side of the wire conductor under a gas atmospheric condition.

The laser beam may be passed via a glass fiber or optical wave guide to the insulated wire conductor passing through a diode laser tunnel, as a result of which the wire conductor is heated locally, and its insulation vaporizes away in a defined manner, so that the wire conductor emerges from the tunnel opening as a bare copper wire and can be placed or embedded onto or into a substrate. During the interconnection process of the wire conductor to the terminal area of a chip through thermal compression bonding, there is no risk of contamination from the insulation and the technique significantly enhances the bond force of the wire conductor to the terminal area of the chip.

The present invention may make use of techniques such as may have been disclosed in U.S. Provisional Application 60/887,294 filed 30 Jan. 2007 by Finn (“S7”), incorporated by reference herein. The S7 provisional patent application describes, for example, that the chip or chip module may be attached to a synthetic substrate by applying thermal energy to the chip, resulting in the softening of the substrate and the sinking of the chip into the substrate. The source of heat can be from a hot iron, heated diamond tool or the chip can be ultrasonically pressed into the substrate. In this case, the chip and the antenna are on a common substrate. The process for bonding the wire ends of the antenna to the chip on a common substrate can be as follows:
After the chip is sunk into the substrate,
   the wire is first placed or embedded onto or into the substrate;
   the wire is passed over the first terminal area of the chip;
   the wire is placed or embedded onto or into the substrate to form an antenna;
   upon completion of the antenna the wire is passed over the second terminal area and then placed or embedded into the substrate before cutting the wire.
   In the next step, the wire ends of the antenna residing over the terminal areas are bonded to the terminal areas of the chip.

The insulation of the wire can be partially removed at the position where the wire passes over the terminal areas. Thermal energy may be used to interconnect end portions of the antenna wire to terminals (terminal area) of the chip (or chip module) using a laser.

As described in the S7 provisional patent application, the conventional interconnection method of thermal compression bonding may be replaced by (for example, without limitation) a 40 watt Nd:YAG (neodymium-doped yttrium aluminum garnet; Nd:Y₃Al₅O₁₂) solid state laser which typically emits light with a wavelength of 1064 nm, in the infrared. However, there are also transitions near 940, 1120, 1320, and 1440 nm. The Nd:YAG laser can operate in both pulsed and continuous mode. In using a Nd:YAG laser for interconnection, it is not necessary to remove the insulation prior to bonding.

The wire ends of the antenna are mechanically fixed during the transmission of the laser beam via a glass fiber to the bond position. The pulse duration of the laser may be approximately 1 millisecond.

The present invention may make use of techniques such as may have been disclosed in U.S. patent application Ser. No. 11/831,987 Aug. 1, 2007 by Finn (“S12”) incorporated by reference herein. The S12 provisional patent application describes, for example, methods of mounting an antenna wire to the surface of a substrate, having the wire ends of the antenna spanning a recess, so that the wire ends are spaced wider apart than one dimension of a chip or chip module. The chip or chip module may then be moved or manipulated into the recess so that its terminal areas are under the wire ends of the said antenna, or alternatively the wire ends of the antenna may be repositioned to be over the terminal areas of the chip or chip module.

In the present invention, the method of sinking the chip into the substrate using thermal energy as outlined in S7 and the method to interconnect the wire ends of the antenna to the terminal areas of the chip using laser is expanded upon to include the lamination process.

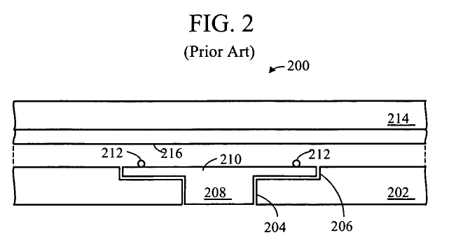

In the abovementioned method to produce an inlay for an electronic passport, the cold lamination process has a number of disadvantages over hot lamination with respect to security and the long term reliability of the product. For example, de-lamination of the cold laminated booklet in hot humid environments, fraudulently peeling back the cover material to reveal the antenna and chip module using steam—the adhesive bonding can be attacked using steam, in cold laminated passport inlays the chip is not fully protected and there is a gap in the material which allows moisture to seep in over time—see 204 in FIG. 2.

In the present invention, a chip module having a mould mass and leads extending therefrom may be mounted to a substrate by:
firstly by providing a cavity (indent, recess) in the substrate layer to accommodate the chip module (such as mould mass of the chip module),
secondly pressing the chip module against the substrate using thermal energy, thus partially sinking the leads of the chip module into the substrate (alternatively, a recess can be milled out of the substrate to accommodate the leads of the chip module),
thirdly embedding a wire, such as a 60 micron wire into the substrate and forming an antenna with a certain wire pitch,
fourthly passing the wire ends of the antenna over the terminal areas in preparation for interconnection,
fifthly placing a transparent synthetic patch such as a polypropylene adhesive tape over the chip module with the wire ends of the antenna residing over the terminals areas so as to fix the position of the chip module relative to the wire ends of the antenna or hot laminating (e.g. ultrasonically or using a hot press) a transparent synthetic patch to the substrate, then in the sixth stage of the process a laser is used to weld the wire ends of the antenna to each terminal area by passing the beam through the transparent synthetic patch.
finally, the substrate with the transponder unit is hot laminated with the cover material. Any attempt to separate the layers of the inlay will result in the destruction of the antenna, the chip module or both. An additional security feature can be a change of inlay color should someone attempt to laminate the inlay a second time.

In reducing the manufacturing cost of the transponder unit, the wire ends of the antenna can be connected directly to a die as outlined in the S4 provisional patent application or to bumps rising above the aluminum pads of a die. The bumps at each pad (terminal) on the die can be straight wall gold bumps having a height of approximately 25 microns and a length and width of 100 microns. For ease of connecting the 60 micron wire to the bumps, mega bumps passing over the active structure of the die may be required.

To protect the die from breakage, a stiffening ring can be placed over the die so as to avoid bending the laminated inlay at the position of the die. To cushion the die in its cavity, a silicon material can be used. To strengthen the tensile strength of the inlay a cotton fleece or noil (noil is a short fiber left over from combing wool or spinning silk) can be used.

As in the case of the chip module,
the bumped die may be partially laminated into the substrate by applying thermal energy to the die for the purpose of sinking the device into the substrate low enough to allow the wire ends of the antenna to pass over the bumps;
embedding a 60 micron wire into the substrate, passing over the first bump, forming an antenna with 4 or 5 turns and passing over the second bump;
placing a transparent synthetic patch such as a adhesive tape (polypropylene) over the die with the wire ends of the antenna residing over the bumps so as to fix the position of the bumped die relative to the wire ends of the antenna or alternatively hot laminating the transparent synthetic patch to the substrate;
then, a laser is used to weld the wire ends of the antenna to each bump by passing the beam through the transparent synthetic patch; and
finally, the substrate with the transponder unit is hot laminated with the cover material.

Any attempt to separate the layers of the inlay may result in the destruction of the antenna, the die or both.

By reducing the thickness of the wire from 80 μm (microns) to 60 μm for the hot lamination process, the contour of the wire antenna cannot be felt at the surface of the inlay. During the wire embedding process, it is also possible to pass an ultrasonic horn over the width of the antenna to further sink the wires of the antenna into the substrate. Another advantage of using a 60 μm wire is that it simplifies the direct connection of the wire ends of the antenna to the bumps on the die.

FIG. 2 illustrates a conventional method of forming a cold laminated inlay 200, exemplary of an inlay for a US passport. In FIG. 2,
the inlay is shown partially exploded
the format may be 183 mm×405 mm, such as for 3 passports (“3up format”)
with 3 transponder units
overall thickness (substrate 202, adhesive and cover 214) approximately 750 microns

In FIG. 2, the following components are shown:
200 Inlay
202 Substrate (355 microns, Teslin)
204 window or cavity punched through substrate 202
206 Indent (ultrasonically formed) to accept lead frame
208 Chip module (with lead frame 210)
210 Lead frame
212 Antenna wire with a diameter of 80 microns
214 Cover material (350-400 microns), coated heavyweight cotton
216 Adhesive (30 microns, hot melt)

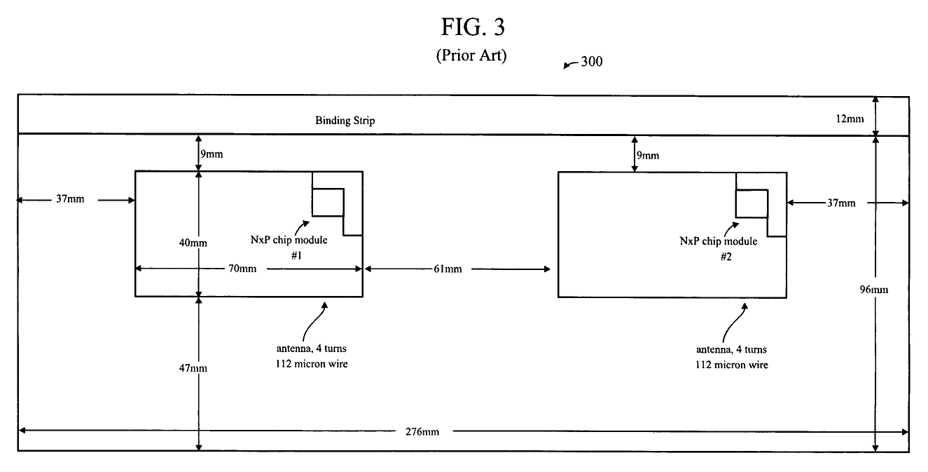

FIG. 3 illustrates a conventional method of making a transparent hot laminated inlay (PET/PETE Structure with 4 layers) in which the wire ends of the antenna are connected to the terminal areas of the chip module using thermal compression (TC) bonding, according to the prior art, and is representative of a British passport.

In the prior art example of FIG. 3, the diameter of the antenna wire is 112 microns.

A major disadvantage of thermal compression (TC) bonding is the ageing of the thermode (electrode) resulting in unreliable bonds. And insulation residue remaining at the bond position, between the wire conductor and the leadframe of the chip module.

In the example of FIG. 3,
the substrate 300 (inlay, which may comprise several layers of substrate or sheets) may be a PET or PETE structure, 4 layers
the format may be 108 mm×276 mm
the substrate may accommodate 2 transponder units (for two passports, “2up format”)
the inlay thickness is approximately 550 microns
the thickness of the binding strip may be 80 microns
the antenna (not shown) may comprise 4 turns of wire
the wire diameter may be 112 microns
the width of the inlay can be laser cut to 80 mm (cut binding strip or other side?)
the chip module may be Infineon Chip Module MCC8-2-2

The antenna (not shown) may be 48 mm×80 mm, having 3 turns+1 blind turn, may have a threshold resonance frequency after lamination of 16.5+/−0.8 MHz and may have an unloaded resonance frequency of 18.6+/−0.8 MHz.

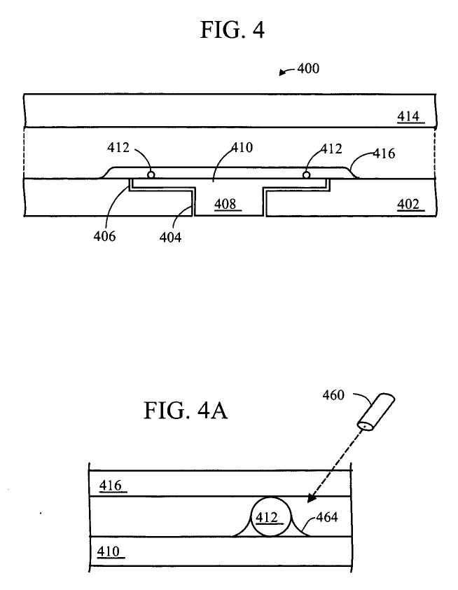

FIG. 4 illustrates an inlay 400, comparable in some respects to the inlay 200 shown in FIG. 1 in that it may be used for a US Passport. The inlay 400 is a two-layer inlay comprising a substrate 402 and a cover 414.
400 Inlay
402 Substrate (355 microns, e.g. Teslin, PET/PETE structure, Polycarbonate, Paper coated substrate, etc.) The substrate 402 is generally planar, having a surface.
404 Window or cavity (punched) through substrate 402
406 Indent (milled recess)—or—thermal energy applied to the chip module for the purpose of sinking into substrate
408 Chip module (with lead frame 410)
410 Lead frame
412 Antenna wire with an exemplary diameter of approximately 60 microns. End portions of the antenna wire pass over (are disposed on or atop) respective terminal areas of the chip module (or lead frame thereof).
414 Cover material (350-400 microns), coated heavyweight cotton. The cover 414 is generally planar, and is disposed as shown over the substrate 402 (with chip module and patch 416 in place).
416 Transparent synthetic patch (adhesive tape) to hold in place the wire ends (end portions) of the antenna to the terminal areas of the chip module and at the same time to adhesively attach (secure) the patch to the substrate

The transponder chip or chip module may have a mould mass and a lead frame extending from the mold mass, or may be another packaged form of chip having terminal areas, and may be recessed into the substrate, as shown.

The inlay 400 may be a hot laminated inlay using laser technology for interconnection and patching to protect the chip module and terminal areas, according to an embodiment of the invention.

Generally, a process of making the inlay 400 may comprise the following steps,
1. the indent 406 may be milled, such as using laser ablation (laser ablation works well with Teslin and polycarbonate, but not with PVC)
2. position the wires so that end portions pass over terminals of the chip (module), and tape the end portions of the wire in place using a clear adhesive tape
3. bond the end portions of the wires to the terminals using a laser, through the tape

FIG. 4 illustrates a hot laminated inlay in which the chip 408 and the wire termination areas are protected by a transparent synthetic patch, adhesively attached or laminated to the underlying substrate and the interconnection of the antenna wires to the terminal areas of the chip is by means of laser welding. As the laser beam passes through the transparent patch there is no damage to its surface. Laser welding, or bonding, is discussed hereinbelow with respect to FIG. 10.

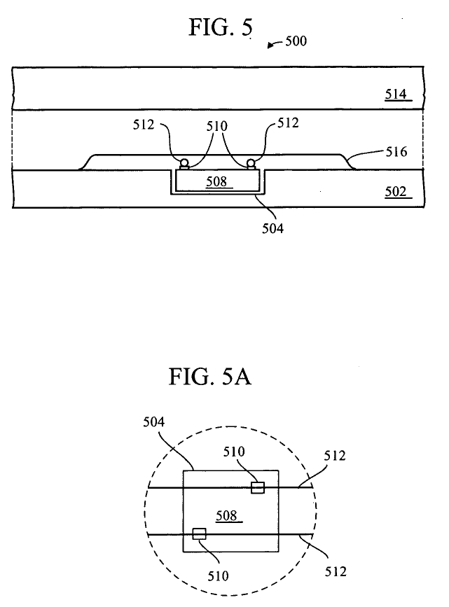

It should be noted that the patch 416 (see also 516, below) is adhesive, and holds (fixes) in place the wire 412, the chip 408, and substrate 402, relative to one another, initially, without and before bonding. The end portions of the wire are positioned touching the terminals of the chip 408 (or lead frame 410), held in place for subsequent bonding. Similar comments apply to the embodiment shown in FIG. 5, below.

Holding the end portions of the wire in place in this manner facilitates laser bonding, as it prevents the wire from moving while being bonded. For laser bonding, the patch should be transparent.

In general, the patch 416 the patch 416 (see also 516, below) holds everything in place for subsequent lamination, or application of the cover 414 (514).

An alternative to laser bonding is to apply a dollop of conductive glue or solderable material to the interface between the end portions of the wire and the chip terminals (or lead frame terminal areas). The glue may be allowed to cure, without or without heat. If the patch is transport, infrared light could be used to facilitate curing. A laser could be used for this purpose. Solderable material may similarly be heated, and using a transparent patch permits infrared light such as from a laser to re-flow the solderable material.

FIG. 4A illustrates a patch 416 holding down a wire 412 onto a terminal area of the lead frame 410 (this is exemplary of any situation where a wire is held to a corresponding terminal or terminal area of a chip or chip module, such as in FIG. 5). A laser 460 (or other heat source) is used to warm or re-flow an adhesive or solderable material 464, respectively, thereby forming a bond (secure mechanical electrical connection) between the wire and the terminal area.

In FIG. 4, the cavity 404 is punched entirely through the substrate 402. In FIGS. 5 and 6B, a recess which extends only partially through the substrate is shown.

FIG. 5 illustrates an embodiment of a hot laminated inlay using laser technology for direct connection and patching to protect the positioning of the antenna wires relative to the bumps (terminal areas) of the die (chip).
500 Inlay
502 Substrate (355 microns, e.g. Teslin, PET/PETE structure, Polycarbonate, Paper coated substrate, etc). The substrate 502 is generally planar, having a surface.
504 recess for a die 508 embedded into the substrate 502, such as 260 μm deep
508 a bumped die, which may be backlapped and polished to a thickness of 200 μm
510 bumps on the die 508, such as gold, 25 μm high and 100 μm wide
512 antenna wire, having a diameter such as approximately 60 μm. End portions of the antenna wire pass over (are disposed on or atop) respective terminals areas (bumps) of the chip module (bumped die).
514 cover material, thickness 350-400 μm, coated heavy-weight cotton. The cover 514 is generally planar, and is disposed as shown over the substrate 502 (with chip module and patch 516 in place).
516 transparent synthetic patch, such as adhesive tape, having an adhesive backing which secures it to the surface of the substrate 502. The patch 516 may hold in place the wire ends of the antenna to the bumps 510 of the die 508 and at the same time to attach the patch to the substrate

In this example, rather than having a mould mass and a lead frame extending from the mold mass, the chip module is a bumped die having terminal areas is shown, and may be recessed into the substrate, as shown.

The total thickness of the inlay 500 (substrate plus cover) may be approximately 750 microns, and the inlay can be trimmed back to 80 mm width such as by laser cutting.

FIG. 5A is a top, magnified view of a portion of FIG. 5, particularly showing the chip (508), recess (504), bumps (510) and end portions of the antenna wire (512).

FIG. 5 illustrates a hot laminated inlay 500 in which the die 508 and the wire termination areas (bumps) are protected by a transparent synthetic patch, adhesively attached or laminated to the underlying substrate and the direct connection of the antenna wires to the bumps of the die is by means of laser welding. As the laser beam passes through the transparent patch there is no damage to its surface.

The inlay 500 is comparable in some respects to the inlay 200 shown in FIG. 2 in that it may be used for a US Passport. The inlay 500 may be a two-layer inlay comprising a substrate 502 (compare 402) and a cover 514 (compare 414).

### Method and Apparatus to Produce A Transponder Site

### On an Inlay Using Laser Ablation

An embodiment of the invention relates generally to techniques of preparing a high frequency or ultra high frequency transponder site on an inlay, by removing material from a synthetic film or coated paper for the purpose of creating a recess to accommodate a radio frequency identification chip or chip module as well as laying trenches in the film to accept a wire conductor in forming an antenna, followed by bonding end portions of the antenna wire to terminals (bond pads) of the transponder chip disposed in a recess in the film substrate.

In some embodiments, the present invention may make use of some of the techniques disclosed in commonly-owned, copending U.S. patent application Ser. No. 11/831,987 filed Aug. 1, 2007 (“S12”), incorporated by reference herein, which discloses a method of producing an electronic passport inlay. FIG. 6A of S12 illustrates the design of the current inlay 600 for passports. Generally, a contactless (RFID) chip module 608 is disposed in a recess in a substrate 604 comprising a Teslin™ sheet. FIGS. 6A and 6B of S12 are reproduced as FIGS. 6A and 6B, herein.
Teslin™ is a synthetic printing media, manufactured by PPG Industries. Teslin™ is a waterproof synthetic material that works well with an Inkjet printer, Laser printer, or Thermal printer. Teslin™ is also single-layer, uncoated film, and extremely strong. In fact, the strength of the lamination peel of a Teslin™ sheet is 2-4 times stronger than other coated synthetic and coated papers. Teslin™ comes in the sizes of 7 mil to 18 mil, though only sizes 10 mil and 14 mil are sized at 8.5″ by 11″, for printing with most consumer printers. Also available are perforated versions of Teslin, specifically, 2up, 6up, and 8up.

The substrate 604 can be considered to be a multi-layer substrate with the Teslin™ sheet forming a top layer 604a and the passport cover page forming a bottom layer 604b. In this example of a passport, a cover page 604b for the passport, which may be paper, is laminated using a hot-melt adhesive 605 to the front surface of the Teslin™ sheet 604a, in a cold lamination process. The adhesive 605 may have a thickness of approximately 20 μm.

The chip module 608 is disposed in a recess 606 in the approximately Teslin™ sheet 604a, which may be formed using an ultrasonic stamp process in the front (bottom, as viewed) surface of the sheet.

The Teslin™ sheet 604a may have a thickness of approximately 355 μm. The passport cover page 604b may have a thickness of approximately 350 μm.

The Teslin™ sheet 604a extends from an outer edge of the overall passport booklet, to the binding, which is the common edge of two adjacent pages. A hinge gap 609 is shown, to the left of which is the Teslin™ sheet 604a, and to the right of which may be a conventional passport page 611 (or more Teslin™). Notice that the recess 606 extends all the way through the Teslin sheet 604a, and the back (top, as viewed) of the mold mass of the chip module 608 is exposed.

An antenna wire 610, comprising self-bonding coated wire, which may have a diameter of 112 μm is pressed (embedded) partially into the front surface of the Teslin™ sheet 604a. The chip module 608 has two terminals (not explicitly shown) to which the two end portions (wire bridges) 610a and 610b are bonded.

There are a number of problems associated with the passport construction described hereinabove. For example, the chip module is exposed and moisture can enter between the mould mass and the Teslin sheet. The mould mass protecting the chip is itself not protected from the environment. A sudden shock to the top of the chip module may render it non-functional. Also, the wire being used is self-bonding coated wire which is not embedded into the Teslin substrate, but rather adhesively attached to the substrate. Then, in a further process step, the antenna is pre-pressed into the substrate using a hot lamination process. The area in the Teslin substrate around the position of the chip module is formed using an ultrasonic stamp. It is not known for certain how the material will react in the field, perhaps causing bulges in the cover material (air pockets forming) or in the Teslin material or both.

As disclosed in S12, generally, some of the aforementioned problems may be solved by introducing a two-level recess layer in the Teslin material. The recess may be milled out of the material. The recess can be round or can be conventional rectangular (including square). The chip module is protected by a silicon cushion and is not exposed to the environment.

FIG. 6B illustrates the design of an inlay 650 for passports. Generally, a contactless (RFID) chip module 658 (compare 608) is disposed in a recess 656 (compare 606) in a substrate 654 (compare 604) comprising a Teslin™ sheet.

The substrate 654 can be considered to be a multi-layer substrate with the Teslin™ sheet forming a top layer 654a (compare 604a) and the passport cover page forming a bottom layer 654b (compare 604b). In this example of a passport, a cover page 654b for the passport, which may be paper, is laminated using a hot-melt adhesive 605 to the front surface of the Teslin™ sheet 604a, using a cold or hot lamination process. The adhesive 605 may have a thickness of approximately 20 μm. Alternatively, a cold laminating process can be used. A double-sided tape could be used.

The chip module 658 is disposed in the recess 656 in the approximately Teslin™ sheet 654a, which may be formed using a high speed milling tool (not shown) to create a stepped (larger area, followed by a smaller area) recess in the front (bottom, as viewed) surface of the sheet. The recess 656 does not go all the way through the layer 604a, but rather stops, leaving at least approximately 35 μm of material behind the chip module 658. This ensures that moisture will not enter.

The recess 656 is sized and shaped to accommodate a thin layer 657 of synthetic cushion material (such as silicone rubber), within the recess, between the chip module 658 and the substrate layer 654a, beneath the chip module 658. This provides some protection against shock, as well as against moisture.

The Teslin™ sheet 654a may have a thickness of approximately 355 μm. The passport cover page 654b may have a thickness of approximately 350 μm. The cover 654b may be laminated to the sheet 654a using a hot melt adhesive 655.

The Teslin™ sheet 654a extends from an outer edge of the overall passport booklet, to the binding, which is the common edge of two adjacent pages. A hinge gap 659 is shown, to the left of which is the Teslin™ sheet 654a, and to the right of which is a conventional passport page 661 (or more Teslin™). Notice that the recess 656 does not extend all the way through the Teslin sheet 654a, and therefore the back (top, as viewed) of the mold mass of the chip module 658 is not exposed.

An antenna wire 660, comprising insulated wire, which may have a diameter of 70 μm is embedded directly into the front surface of the Teslin™ sheet 654a. The chip module 658 has two terminals (not explicitly shown) to which the two end portions (wire bridges) 660a and 660b are bonded, as described hereinabove. It can be noted that the antenna wire 660 is substantially fully embedded (in contrast with the antenna wire 610 which is only partially embedded. This can be achieved by using a higher frequency in the embedding tool, such as 60 Hz, rather than 30 Hz.

### Mounting the Antenna Wire

A conventional method to produce an inlay site containing a high frequency RFID chip and an antenna embedded into a multi-layer substrate and connected to the terminals (terminal areas) of the RFID chip is to first position the RFID chip in a recess, supported by a lower substrate layer, then start embedding (countersinking) a wire conductor onto or into the top substrate layer in the direction of the RFID chip, then guiding the wire conductor over a first terminal area of the RFID chip, then continue the embedding process by forming an antenna in the top substrate layer with a given number of turns, then guiding the wire conductor over the second terminal area, and finally embedding the wire conductor again into the top substrate layer before cutting the wire to complete the high frequency transponder site. In a next stage of the production process, the wire ends passing over the terminal areas are interconnected by means of thermal compression bonding. Adhesively placing a wire conductor onto the top substrate layer is an alternative to embedding, and typically involves self-bonding coated wire conductor.

A wire embedding apparatus may be an ultrasonic wire guide tool, known as a “sonotrode”, with a wire feed channel (capillary) passing through the center of the wire guide tool. The wire conductor is fed through the wire guide tool, emerges from the tip, and by application of pressure and ultrasonic energy the wire conductor is “rubbed” into the substrate, resulting in localized heating of the wire conductor and subsequent sinking of the wire conductor into the substrate material during the movement of the wire guide tool. A wire placement apparatus may also be an ultrasonic tool similar in function to an ultrasonic horn which heats the wire to form an adhesion with a substrate.

U.S. Pat. No. 6,698,089 (“089 patent”), incorporated by reference in its entirety herein, discloses device for bonding a wire conductor. Device for the contacting of a wire conductor in the course of the manufacture of a transponder unit arranged on a substrate and comprising a wire coil and a chip unit, wherein in a first phase the wire conductor is guided away via the terminal area or a region accepting the terminal area and is fixed on the substrate relative to the terminal area or the region assigned to the terminal area by a wire guide and a portal, and in a second phase the connection of the wire conductor to the terminal area is effected by means of a connecting instrument. FIGS. 1 and 2 of the 089 patent show a wire conductor 20 being embedded in a surface of a substrate 21, by the action of ultrasound. FIG. 3 of the 089 patent shows a wiring device 22 with an ultrasonic generator 34, suitable for embedding the wire. It is believed that the wiring device in the 089 patent can also be used for adhesively placing a wire.

Using the ultrasonic technique as described above, the time to embed a wire conductor into a non-conductive substrate like PVC, forming an antenna with 4 turns and positioning the wire ends of the antenna over the terminal areas of an RFID chip in preparation for bonding, and thus create a transponder site, is approximately 10 seconds. Depending on the durability of the material the embedding time can increase, for example in the case of Teslin, the embedding speed has to be reduced in order to countersink the wire conductor properly into the material. This means that the embedding speed has certain limitations, if the surface finish quality of the transponder site is to be constant.

### Removing Insulation

Conventionally (in the prior art), an insulated wire conductor is bonded to the terminal area(s) of a chip using thermal compression bonding. This is a welding process in which the insulated wire conductor is bonded to the terminal area(s) of a chip by passing a current through a thermode which holds the wire conductor under force against the terminal area of the chip. The first impulse of current removes the insulation, while the second impulse results in the diffusion of the wire conductor with the terminal area of the chip.

If the antenna wire is an insulated wire, having one or more coatings to assist (for example) in mounting by adhesively placing the antenna wire on the substrate, the coating(s) (self bonding coat and insulation layer) should be removed prior to bonding. Removal of the coating(s) (insulation) from an insulated wire (importantly from a portion of the wire that will be bonded to the terminal(s) of the transponder chip) may involve using apparatus such as a laser or a hot iron to remove the coating(s)), and can be done (performed), in preparation for bonding, either (i) during mounting the antenna wire, or (ii) after having mounted the antenna wire to the substrate.

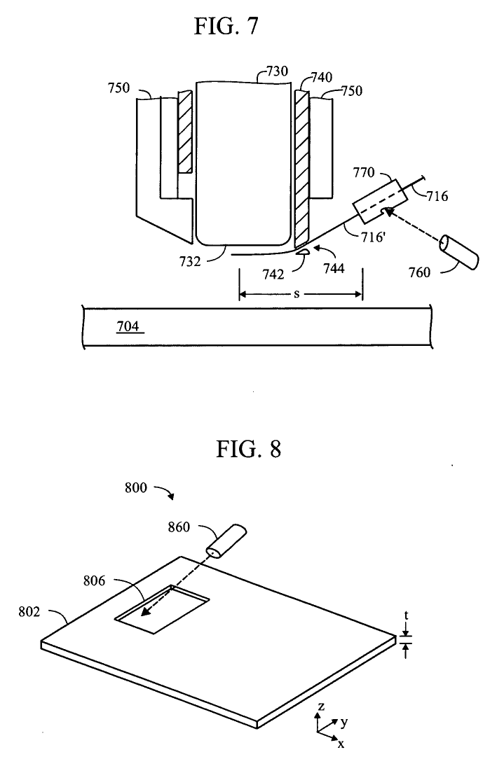

Reference is made to FIGS. 6, 7A and 7B of S9, incorporated by reference herein.

A self-adhering wire may comprise:
a metallic core, having a diameter;
a first non-metallic coating disposed on the surface of the metallic core; and
a second non-metallic coating disposed on the surface of the first non-metallic coating

The core may comprise copper, aluminum, doped copper, gold, or Litz wire, and may have a diameter of 0.010-0.50 mm (AWG 24-58) (0.00 mm=100 micron).

The first coating, or “base coat” may comprise modified polyurethane, and may have a thickness of only a few microns.

The second coating, or “bond coat” may comprise polyvinylbutyral or polyamide, and may have a thickness of only a few microns.

Although an insulated wire can be bonded to a terminal of a chip, it is desirable to remove the insulation from the wire prior to interconnection (bonding to the terminal of the transponder chip) to ensure that no insulation residue is under the wire conductor at the bond site.

According to an embodiment of the invention, laser ablation may be used to remove insulation from the antenna wire, to enhance subsequent bonding. For example,
(i) before passing through the eye of a wire guide, or the like, which is used for mounting the wire to the substrate, the wire may pass through an insulation-removal station, which may comprise a nozzle where laser light can be introduced via a glass fiber, to remove (ablate) the insulation from the wire. After passing through the insulation-removal station, the wire is no longer coated. The removal of insulation may readily be performed only on portions of the wire which will subsequently be bonded to terminals of the transponder chip.
(ii) after mounting the wire to the substrate, insulation may be removed from end portions of the wire, preferable before the transponder chip is in place. (note, this is discussed in greater detail in S9).

It may be advantageous to use a ultra-violet (UV) laser to remove the insulation. The UV laser uses optical directing systems to remove the insulation, and the wire can be flooded (or protected by) with an inert gas, such as nitrogen, to avoid oxidation of the bare (such as copper) wire before bonding. In addition, the wire can be metalized with a coat solder or any metal to enhance the interconnection (bonding) process.

FIG. 7 illustrates removing insulation while mounting the wire. An exemplary embedding tool 700 is shown. A wire 716 is shown passing through an eye 744 in a wire guide 740 of the embedding tool 700. An end 732 of the sonotrode 730 pushes the wire against a substrate 704, for mounting thereto. A wire cutter 750 is shown.

The purpose of the wire guide 740 is to guide wire 716 from an external supply (not shown) to under the end 732 of the sonotrode 730, so that the wire 716 can be embedded in to the surface of a substrate 702. The end 742 of the wire guide 740 is provided with a small feed hole (or “eye”, as in eye of a needle) 744 through which the wire 716 can be inserted (or “threaded”, akin to threading a sewing machine needle). In FIG. 7A, the wire 716 can be seen passing through the wall of the wire guide 740, at approximately a 45-degree (30-60 degree) angle.

Before passing through the eye 744 of the wire guide 740, the wire 716, which is a coated wire, passes through an insulation-removal station 770, which may comprise a nozzle where laser light from a laser 760 can be introduced via a glass fiber, to remove (ablate) the insulation from the wire 716. After passing through the insulation-removal station 770, the wire is no longer coated, as indicated by the primed reference numeral 716′. As shown in the drawing, a distance “s” represents how far in advance, along the length of the wire, the insulation needs to be removed to control its final destination.

### Laser Ablation, Generally

According to an embodiment of the invention, laser ablation may be used to remove material from the synthetic film or substrate for the purposes of (i) creating a recess (cavity) or pocket to accommodate a chip or chip module and (ii) to form a groove (or trench, or channel) in the film to accept (recess) a wire conductor. A laser may also be used to remove insulation from the wire, as described above (FIG. 7). A laser may also be used to weld (bond) the end portions of the antenna wire to the terminals of the chip (or chip module, or lead frame).

In preparing a transponder site, film supplied in endless web form, is laser cut to form sheets which form part of a multi-layered inlay. The core layer of the multi-layered inlay contains an array of RFID chips connected to their respective antenna. Each transponder site on the inlay can be laser engraved with an identification number.

The first step of the process to produce a transponder site is to form a cavity or pocket in the film to accept a chip or chip module using the technique of laser ablation, then to form grooves or trenches in the film to accept a wire conductor as part of a high frequency (HF) or ultra high frequency (UHF) antenna. The wire conductor may be insulated and before bonding of the wire conductor to a terminal area of a chip or chip module, the insulation may be removed per laser.

In the case of an UHF transponder, the RFID chip can be first bonded to a dipole antenna and then the complete arrangement (chip with two wings of wire conductor) is placed on the film, whereby the chip resides in the laser ablated cavity or pocket and the wire conductors are pressed into the laser ablated grooves or trenches.

In the case of an HF transponder, the wire conductor be first scribed into the laser ablated grooves or trenches which form an antenna with several turns, with the wire ends of the antenna placed adjacent to the cavity or pocket accepting the chip or chip module. After the insulation is removed and the chip or chip module is placed in the laser ablated cavity or pocket, the wire ends of the antenna are positioned over the terminal areas for bonding.

### Creating a Recess

In the case of a multi-layer substrate, such as 104 (FIG. 1B), a recess 106 may be formed punching out a hole completely through one layer 104a of the substrate. A chip 108 inserted into the recess 106 will be supported by an underlying layer 104b.

As mentioned above (FIG. 6A), a recess 606 may be formed in the Teslin™ sheet 604a using an ultrasonic stamp process in the front (bottom, as viewed) surface of the sheet. The recess is “stepped”, therefore the chip module 608 which is disposed in the recess will not fall through, even if the recess extends all the way through the sheet 604a.

As mentioned above (FIG. 6B), the chip module 658 may be disposed in the recess 656 in the approximately Teslin™ sheet 654a, which may be formed using a high speed milling tool (not shown) to create a stepped (larger area, followed by a smaller area) recess in the front (bottom, as viewed) surface of the sheet. The recess 656 does not go all the way through the layer 604a, but rather stops, leaving at least approximately 35 μm of material behind the chip module 658. This ensures that moisture will not enter.

In some cases, such as the substrate 654a, it is desired to form a recess (or pocket), rather than a hole though a (or sheet), without the recess extending completely through the substrate. In the case of a substantially planar substrate, this means, of course, that the recess will have a depth that is less than the thickness of the substrate.

FIG. 8 illustrates an exemplary process 800 of forming a recess 806 in a substrate 802, using a laser 860. The substrate 802 may be a single layer of Teslin (for example), having a thickness “t” of 355 μm in the z-direction, and measuring 183 mm×405 mm (3up format) in the x- and y-directions. A typical size for the recess 806, to accommodate a chip with lead frame, may be approximately 5 mm×8 mm, by 260 μm deep.

The laser 860 emits a beam (dashed line), targeted at the substrate 802, to ablate material from the substrate 802 to form the recess 806. The beam may have a diameter of approximately 0.1 mm. The beam may be scanned back and forth, traversing in one direction entirely across the recess area, turning around, and traversing back across the recess area, like plowing a field. Many passes may be required to carve out the entire area of the recess, given that the beam diameter is typically much (such as 10-100 times) smaller than the length or width of the recess. As is known, the beam may be scanned, in any suitable manner, such as with mirrors. Also, the intensity of the beam may be controlled or modulated to control the penetration into the substrate. For example, a pulse-width modulated beam may be used. The laser may be a a UV laser (355 nm) with a power ranging from 20 to 70 watts.

The process of using a laser in this manner, rather than (for example) a conventional rotating milling tool, may be referred to as “laser milling”. The technique described herein may be particularly beneficial for applications where it is desired to form a “pocket” type recess which intentionally does not extend all the way through the substrate or sheet (in other words, the recess or pocket extends only partially through the substrate). Mechanical milling can be difficult. On the other hand, laser milling can be very effective for Teslin and polycarbonate substrates. For PVC, laser milling is less effective.

### Mounting the Antenna Wire

As mentioned above, the antenna wire may be mounted to the surface of the substrate by embedding (countersinking) it into the surface of the substrate or adhesively placing (adhesively sticking) the antenna wire on the surface of the substrate. With embedding, the wire is only partially embedded, such as approximately half its diameter. In other words, a 100 μm diameter wire may protrude approximately 50 μm from the surface of the substrate. And, in the case of adhesively sticking, a 100 μm diameter wire may protrude approximately 100 μm from the surface of the substrate.

For applications such as driver's license or passports, it is generally not desirable that the wire extend above the surface of the substrate. As discussed hereinabove, the chip may be recessed (see, e.g., FIG. 6B) so as to be substantially contained within the substrate (or sheet), without sticking out and creating a bump.

According to an embodiment of the invention, the wire may also be recessed to be substantially entirely contained within the substrate. In other words, the wire will be substantially entirely recessed below the surface of the substrate. Generally, this may be accomplished by creating a groove (or trench, or channel) in the surface of the substrate to accept the wire. For example, for a 60 μm diameter wire, a groove which is approximately 60 μm deep may be formed into the surface of the substrate, and the wire is laid (inlaid, pressed, sunk) into the groove.

The groove may simply be a U-shaped cutting in the substrate, formed by a mechanical tool, or by a hot mold process, or by a laser. The groove (channel) may be less deep than the diameter of the wire and, as the wire is laid down into the groove, it may be pressed further into the substrate. Or, after the entire antenna wire is laid down, the substrate may be placed in a press which may further sink the antenna wire into the substrate. The wire may be warmed. The process may be performed in a warm environment to soften the substrate.

For a wire having a diameter of 60-80 μm, for example, a beam having a diameter of 0.1 mm (100 μm) would create a groove sufficiently wide to receive the wire. Multiple passes (as was the case with forming a recess) would not be required.

The groove may be slightly narrower than the diameter of the wire, and as the wire is being laid down, the material of the substrate may retract to receive the wire, holding it in place. Generally, the wire typically has a circular cross-section (but may have other cross-sections, such as a ribbon wire), and the groove may have a substantially rectangular cross-section. For example, a 60 μm wide groove may receive and retain in place an 80 μm diameter wire. The wire may be warmed as it is being laid down (scribed, sunk) into the trench (groove) to facilitate its entry into the trench.

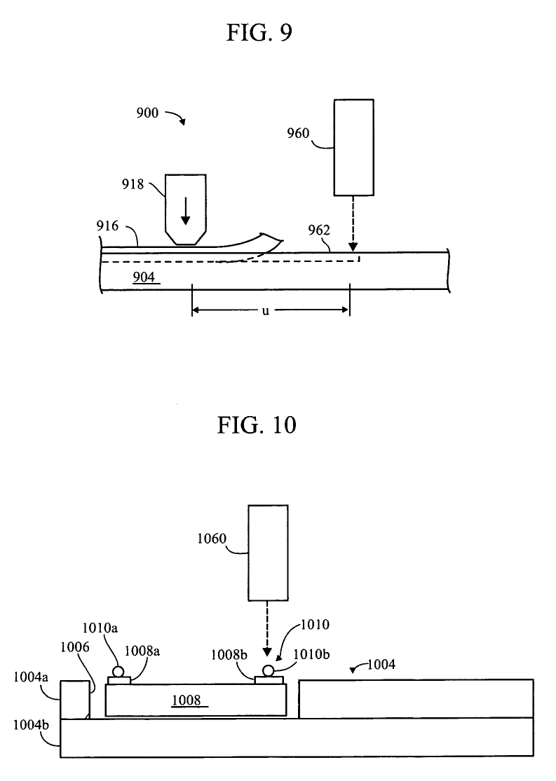

FIG. 9 illustrates using a laser 960 to form a groove 962 in a surface of a substrate 904. A wire 916 is shown being laid down into the groove 962, from left-to-right, and may be urged into the groove 962 by a simple pressing tool (or wheel) 918. The wire 916 may be laid into the groove 962 during formation of the groove (channel), by following after the laser a distance “u”.

Generally, the channel facilitates holding the wire in place. For example, a 100 micron diameter wire can be inserted (with some pressure) into a narrower, such as 95 micron wide channel (the depth of the channel should be at least half the diameter of the wire, so that the wire can be embedded “over center”), and will stay in place. It is beneficial that this can be done without requiring an ultrasonic embedding tool. As mentioned above, mounting a wire to the substrate is typically done by ultrasonically embedding the wire into the substrate, or ultrasonically causing a self-bonding wire to adhere to the substrate. The channeling technique disclosed herein can proceed faster than the ultrasonic techniques, and sheets can be prepared with wire channels, off-line, then the wire can be installed in a simple embedding machine which does not need ultrasonics.

### Laser Bonding (Welding)

As mentioned above, a laser can advantageously be used in lie of thermal-compression (TC) bonding.

FIG. 10 is similar to FIG. 1B, but is shown using a laser 1060 to effect bonding to the terminals of the chip module, rather than the bond head 118. The other elements are similar, including:
substrate 1004 (compare 104), which may comprise at least two layers 1004a and 1004b
a recess 1006 (compare 106) in the substrate, through the top layer of the substrate
a chip module 1008 (compare 108) disposed in the recess, and having two terminals 1008a and 1008b
an antenna wire 1010 (compare 110) forming an antenna on or in the surface of the substrate, and having two end portions 1010a and 1010b

The end portions 1010a and 1010b are shown located on the corresponding terminals 1008a and 1008b of the chip module 1008. The laser 1060 emits a beam to connect (weld or bond) the end portions of the antenna wire to the respective terminals. The beam can pass through a transparent patch such as adhesive tape (omitted from this figure for illustrative clarity), as described above (see FIGS. 4 and 5, 416 and 516).

### Bringing it All Together

Various transponder inlays have been shown, as well as various techniques for using a laser as a tool for making certain features of the inlay.

The laser 1060 (FIG. 10) used for bonding may, for example, be a 40 watt Nd:YAG (neodymium-doped yttrium aluminum garnet; Nd:Y₃Al₅O₁₂) solid state laser which typically emits light with a wavelength of 1064 nm, in the infrared. However, there are also transitions near 940, 1120, 1320, and 1440 nm. The Nd:YAG laser can operate in both pulsed and continuous mode. In using a Nd:YAG laser for interconnection, it is not necessary to remove the insulation prior to bonding.

The laser 960 (FIG. 9) used for forming a channel 962 for the wire 916 may for example, be a 20-70 watt laser operating at 355 nm (ultraviolet).

The laser 860 (FIG. 8) used for forming the recess 806 may for example, be a 20-70 watt laser operating at 355 nm (ultraviolet).

The laser 760 (FIG. 7) used for removing insulation from the wire 716 may, for example be a 70 watt diode laser (808 nm, ultraviolet) connected to a glass fiber (400 microns), to remove a section of insulation layer (polyurethane) with a thickness of 2 to 4 microns from a moving wire conductor, by directing the laser beam to the side of the wire conductor under a gas atmospheric condition. And the wire can be flooded (or protected by) with an inert gas, such as nitrogen, to avoid oxidation of the bare (such as copper) wire before bonding.

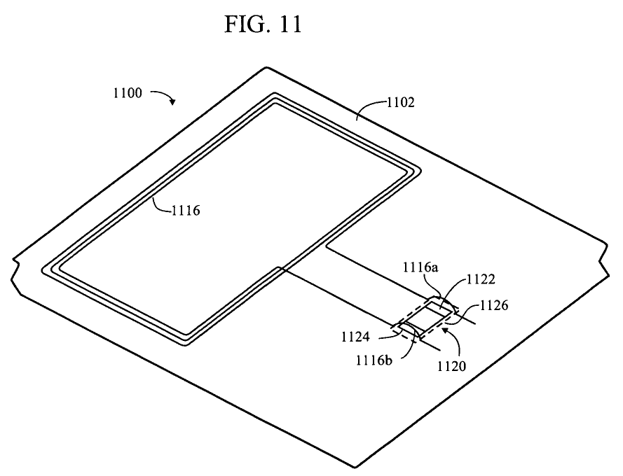

FIG. 11 is a perspective view of an inlay substrate 1100 comprising:
a transponder site 1102
a HF antenna 1116 having two end portions 1116a and 1116b
a HF chip module 1120 having two terminal areas 1122 and 1124
a cavity or recess 1126 in the substrate to accommodate the chip module 1120

In FIG. 11, the two end portions 1116a and 1116b are shown as being pre-positioned and formed as free-standing loops (similar to wire-bonding loops) along side of (adjacent to) corresponding ones of the two terminal areas 1122 and 1124. The loops are in a plane which is more-or-less perpendicular to the plane of the substrate. As described, for example, in S5 (see FIG. 1A therein), this is so that the antenna may be mounted to the substrate before the chip is installed. The chip can be installed between the loops, into the recess 1126. Then, the loops can be manipulated (re-positioned, drawn in) downwards onto the chip terminals for bonding thereto.

The substrate 1100 may be a single-layer sheet, and after the antenna 1116 and transponder chip 1120 are mounted and connected, another sheet (not shown) may be applied over it (compare 414 and 514, above). The recess 1126 may be formed by laser milling. The antenna wire 1116 may be scribed into laser-formed grooves in the substrate 1100. The end portions 1116a, 1116b of the wires may have insulation removed therefrom, and may be welded to the terminals 1122, 1124 of the chip using a laser. Each of these features may be used alone, or in various combinations with one another.

Other tools and techniques, disclosed in related cases, may also be incorporated. For example, flattening the wire, as disclosed in S14, wherein,

FIG. 8D illustrates a technique for shaping (flattening) the wire, in preparation for bonding. A substrate 874 (compare 204) has a recess 876 (compare 206) extending through upper layers 874a (compare 104a) thereof, and slots 877a and 877b (compare 220a and 220b) extending from opposite side edges of the recess 876 completely through the substrate 874, including bottom layers 874b (compare 104b) thereof. End portions 880a and 880b (compare 210a and 210b) of an antenna wire 880 (compare 210) extend as “wire bridges” across the slots 877a and 877b.
Before installing a chip 878 (compare 208) in the recess 876, a punch 890 is brought down on the wire bridges 880a and 880b to flatten out the wire from its initial circular cross-section to a flatter cross-section. To facilitate this shaping, the substrate may be disposed on a surface 892 functioning as an anvil, having raised portions 894a and 894b which fit up into the slots 877a and 877b so that the wire does not break when shaping it.
This shaping (flattening) step can be done before or after the step of removing insulation from the wire bridges. In this figure, the wire bridge 880a is shown as having already been flattened, and the wire bridge 880b is in the process of being flattened.

While the invention has been described with respect to a limited number of embodiments, these should not be construed as limitations on the scope of the invention, but rather as examples of some of the embodiments. Those skilled in the art may envision other possible variations, modifications, and implementations that are also within the scope of the invention, based on the disclosure(s) set forth herein.

What is claimed is:

1. Transponder inlay comprising:
a substrate having a surface;
a transponder chip module recessed into the surface of the substrate and having terminal areas;
an antenna wire disposed on the surface of the substrate and having two end portions;
the end portions of the antenna wire are disposed on the terminal areas of the chip module; and
a patch holding in place the end portions of the antenna wire to the terminal areas of the chip module.

2. The transponder inlay of claim 1, wherein:
the patch is transparent.

3. The transponder inlay of claim 1, wherein:
the patch is adhesively attached to the substrate.

4. The transponder inlay of claim 1, further comprising:
a generally planar cover disposed over the substrate, chip module and patch.

5. The transponder inlay of claim 4, wherein:
the cover comprises a coated, heavy-weight cotton material.

6. The transponder inlay of claim 1, wherein:
the chip module comprises a mold mass and a lead frame.

7. The transponder inlay of claim 1, wherein:
the chip module comprises a bumped die.

8. The transponder inlay of claim 1, wherein:
the substrate comprises a material selected from the group consisting of Teslin, PET/PETE, and Polycarbonate.

9. The transponder inlay of claim 1, wherein:
the antenna wire has a diameter of 60 μm.

10. Method of forming a transponder inlay comprising:
recessing a transponder chip module in a surface of a substrate, wherein the chip module has terminal areas;
mounting a wire to the surface of the substrate and forming an antenna;
passing end portions of the antenna wire over the terminal areas; and
placing a patch over the chip module with the wire ends of the antenna positioned over the terminals areas of the chip module.

11. The method of claim 10, wherein the patch is transparent, and further comprising:
using a laser to bond the end portions of the antenna wire to the terminal areas by passing the beam through the transparent patch.

12. The method of claim 10, further comprising:
applying a dollop of conductive glue or solderable material to an interface between the end portions of the wire and the terminal areas.

13. The method of claim 12, wherein the patch is transparent, and further comprising:
using a laser to heat the conductive glue or solderable material.

14. The method of claim 10, wherein:
the patch is adhesively secured to the substrate.

15. The method of claim 10, wherein:
the patch is hot laminated to the substrate.

16. The method of claim 10, wherein:
the chip module is recessed into the substrate by pressing the chip module against the substrate using thermal energy.

17. The method of claim 10, wherein:
the chip module is recessed into the substrate by milling a recess for receiving the transponder chip into the surface of the substrate.

18. The method of claim 17, further comprising:
performing the milling with a laser.

19. The method of claim 17, further comprising:
mounting a cover over the substrate, including the transponder chip module, wire and patch.

20. Method of forming a transponder inlay comprising:
mounting a chip module to a substrate;
mounting an antenna wire to the substrate;
connecting end portions of the antenna wire to terminal areas of the chip module using a laser; and
performing at least one of:
removing insulation from end portions of the wire;
forming a recess in the substrate using laser ablation; and
forming a channel for the antenna wire in the substrate.

21. The method of claim 20, further comprising:
mounting a cover over the substrate, including the chip module and antenna wire.

22. A method of forming a recess in a substrate for a transponder chip module comprising:
forming a recess for the transponder chip module in a surface of the substrate, wherein the recess extends only partially through the substrate.

23. The method of claim 22, wherein a laser is used to form the recess by ablating material from the substrate.

24. The method of claim 23, wherein the laser is scanned across the surface of the substrate to form the recess.

25. The method of claim 22, wherein the substrate comprises Teslin.

26. The method of claim 22, further comprising:
providing synthetic cushion material, in the recess, between the transponder chip module and the substrate.

27. A method of mounting an antenna wire to a surface of a substrate for a transponder chip comprising:
forming a channel for the antenna wire in the surface of the substrate; and
laying down the wire into the channel.

28. The method of claim 27, wherein the channel is U-shaped.

29. The method of claim 27, wherein the channel is formed by a mechanical tool, or by a hot mold process, or by a laser.

30. The method of claim 27, wherein the channel has a depth which is less than a diameter of the wire, and as the wire is laid down into the channel, it is pressed further into the substrate.

31. The method of claim 27, wherein the substrate comprises Teslin.
